(19) United States
(12) Patent Application Publication
(10) Pub. No.: US 2021/0257299 A1
(43) Pub. Date: Aug. 19, 2021

(54) HYBRID INTERCONNECT WITH A RELIABILITY LINER IN WIDE FEATURES

(71) Applicant: International Business Machines Corporation, Armonk, NY (US)

(72) Inventors: Chih-Chao Yang, Glenmont, NY (US); Chao-Kun Hu, Somers, NY (US); Terry A. Spooner, Mechanicville, NY (US); Baozhen Li, South Burlington, VT (US)

(21) Appl. No.: 16/793,883

(22) Filed: Feb. 18, 2020

(51) Int. Cl. H01L 23/528; H01L 23/532; H01L 21/768

(52) U.S. Cl. CPC H01L 23/5283; H01L 23/53238; H01L 21/7684; H01L 21/76843; H01L 21/76877; H01L 23/53266

(57) ABSTRACT

A back-end-of-the-line (BEOL) interconnect structure is provided that includes a hybrid metal-containing electrically conductive structure and a copper-containing electrically conductive structure embedded in an interconnect dielectric material layer. The hybrid metal-containing electrically conductive structure has a first critical dimension and includes an optional diffusion barrier liner and a hybrid metal-containing region. The copper-containing electrically conductive structure has a second critical dimension that is greater than the first critical dimension and includes an optional first diffusion barrier liner, a hybrid metal-containing liner, a second diffusion barrier liner and a copper-containing region. The hybrid metal-containing region and the hybrid metal-containing liner are compositionally the same and include a metal or metal alloy that has a higher bulk resistivity than copper.

### BACKGROUND

The present application relates to back-end-of-the-line (BEOL) technology, and more particularly to a BEOL interconnect structure that includes a hybrid metal-containing electrically conductive structure of a first critical dimension and a copper-containing electrically conductive structure of a second critical dimension greater than the first critical dimension, both of which are embedded in a same interconnect dielectric material layer.

Generally, semiconductor devices include a plurality of circuits which form an integrated circuit fabricated on a semiconductor substrate. A complex network of signal paths will normally be routed to connect the circuit elements distributed on the surface of the substrate. Efficient routing of these signals across the device requires formation of multilevel or multilayered schemes, such as, for example, single or dual damascene wiring, i.e., interconnect, structures.

Within typical interconnect structures, electrically conductive metal vias run perpendicular to the semiconductor substrate and electrically conductive metal lines run parallel to the semiconductor substrate. In conventional interconnect structures, copper or a copper containing alloy has been used as the material of the electrically conductive metal structure.

As the feature size gets smaller and smaller, the interconnect resistance increases and becomes an issue. For example, small feature sizes can lead to a decreased conducting cross sectional area, a decreased copper volume fraction and/or an increased copper resistivity induced by electron scatterings. When a small feature size electrically conductive structure and a wide feature size electrically conductive structure are to be integrated in a same interconnect dielectric material layer, a comprehensive solution of materials, integration and layouts is needed to address the resistance tradeoffs between the narrow features and the wide features.

### SUMMARY

In one aspect of the present application, a back-end-of-the-line (BEOL) interconnect structure is provided. In one embodiment of the present application, the BEOL interconnect structure includes a hybrid metal-containing electrically conductive structure and a copper-containing electrically conductive structure embedded in an interconnect dielectric material layer. The hybrid metal-containing electrically conductive structure has a first critical dimension and includes a diffusion barrier liner and a hybrid metal-containing region. The copper-containing electrically conductive structure has a second critical dimension that is greater than the first critical dimension and includes a first diffusion barrier liner, a hybrid metal-containing liner, a second diffusion barrier liner and a copper-containing region. In accordance with the present application, the hybrid metal-containing region and the hybrid metal-containing liner are compositionally the same and include a metal or metal alloy that has a higher bulk resistivity than copper. Bulk resistivity (or volume resistivity) is a constant value for a certain material at a certain environment (typically measured at 21° C.). The bulk resistivity is a measure of the resistivity across a defined thickness of the material.

In some embodiments, the diffusion barrier liner is omitted from the hybrid metal-containing electrically conductive structure, and the first diffusion barrier liner is omitted from the copper-containing electrically conductive structure. In such an embodiment, the entirety of the hybrid metal-containing electrically conductive structure is composed of the hybrid metal-containing region, and the copper-containing electrically conductive structure is composed of the hybrid metal-containing liner, the second diffusion barrier liner and the copper-containing region.

In another aspect of the present application, a method of forming a back-end-of-the-line (BEOL) interconnect structure is provided. In one embodiment of the present application, the method includes forming an interconnect dielectric material layer that contains at least one first opening having a first critical dimension and at least one second opening having a second critical dimension that is greater than the first critical dimension. A first diffusion barrier layer is then formed on the interconnect dielectric material layer and within both the at least one first opening and the at least one second opening. Next, a hybrid metal-containing layer is formed on the first diffusion barrier layer, wherein the hybrid metal-containing layer completely fills in the at least one first opening, while partially filling the at least one second opening. A second diffusion barrier layer is then formed on the hybrid metal-containing layer, and thereafter a copper-containing layer is formed on the second diffusion barrier layer. A planarization process is then performed to remove the copper-containing layer, the second diffusion barrier layer, the hybrid metal-containing layer, and the first diffusion barrier layer that are present on the interconnect dielectric material layer, while maintaining the hybrid metal-containing layer and the first diffusion barrier layer in the at least one first opening and maintaining the copper-containing layer, the second diffusion barrier layer, the hybrid metal-containing layer and the first diffusion barrier layer in the at least one second opening. In some embodiments, the forming of the first diffusion barrier layer can be omitted.

### BRIEF DESCRIPTION OF THE DRAWINGS

FIG. 1 is a cross sectional view of an exemplary structure that can be employed in accordance with an embodiment of the present application, wherein the exemplary structure includes an interconnect dielectric material layer containing at least one first opening having a first critical dimension and at least one second opening having a second critical dimension that is greater than the first critical dimension formed therein.

FIG. 2 is a cross sectional view of the exemplary structure of FIG. 1 after forming a first diffusion barrier layer on the interconnect dielectric material layer and within both the at least one first opening and the at least one second opening.

FIG. 3 is a cross sectional view of the exemplary structure of FIG. 2 after forming a hybrid metal-containing layer on the first diffusion barrier layer, wherein the hybrid metal-containing layer completely fills in the at least one first opening, while partially filling the at least one second opening.

FIG. 4 is a cross sectional view of the exemplary structure of FIG. 3 after forming a second diffusion barrier layer on the hybrid metal-containing layer.

FIG. 5 is a cross sectional view of the exemplary structure of FIG. 4 after forming a copper-containing layer on the second diffusion barrier layer.

FIG. 6 is a cross sectional view of the exemplary structure of FIG. 5 after performing a planarization process to remove the copper-containing layer, the second diffusion barrier layer, the hybrid metal-containing layer, and the first diffusion barrier layer that are present on the interconnect dielectric material layer, while maintaining the hybrid metal-containing layer and the first diffusion barrier layer in the at least one first opening and maintaining the copper-containing layer, the second diffusion barrier layer, the hybrid metal-containing layer and the first diffusion barrier layer in the at least one second opening.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

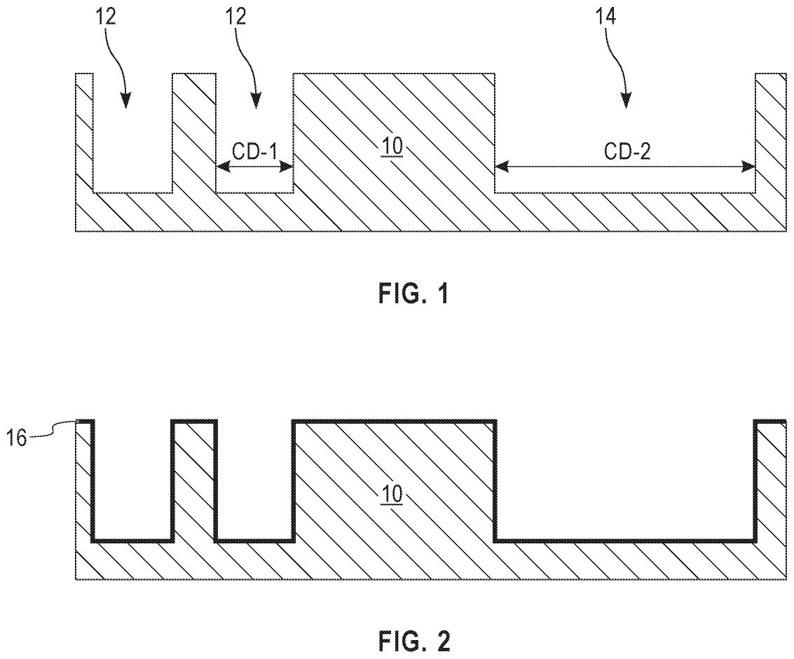

Referring first to FIG. 1, there is illustrated an exemplary structure that can be employed in accordance with an embodiment of the present application. The exemplary structure shown in FIG. 1 includes an interconnect dielectric material layer 10 containing at least one first opening 12 having a first critical dimension (CD-1) and at least one second opening 14 having a second critical dimension (CD-2) that is greater than the first critical dimension (CD-1) formed therein. In the illustrated embodiment shown in FIG. 1, two first openings 12 (each having the first critical dimension (CD-1)) are shown and one second opening 14 having the second critical dimension (CD-2) is shown. Although such an embodiment is described and illustrated, the present application is not limited to an interconnect dielectric material layer 10 that contains two first openings 12 having the first critical dimension (CD-1) and one second opening 14 having the second critical dimension (CD-2). In the present application, each first opening 12 can be referred to as a narrow opening (or feature), while each second opening 14 can be referred to as a wide opening (or feature).

The exemplary structure shown in FIG. 1 is present in the BEOL and is formed upon a substrate (not shown). The underlying substrate can include a metal level that is located above a front-end-of-the-line (FEOL) level that contains one or more semiconductor devices such as, for example, a transistor formed therein. In some embodiments, the metal level is a middle-of-the-line (MOL) level. In other embodiments, the metal level is a lower interconnect level that is positioned beneath the interconnect dielectric material layer 10. In either embodiment, the metal level includes a dielectric material layer that contains at least one metal level electrically conductive structure embedded therein that is connected, either directly or indirectly, to an underlying semiconductor device (not shown) that is present in the FEOL level.

The interconnect dielectric material layer 10 can be composed of an inorganic dielectric material and/or an organic dielectric material. In some embodiments, the interconnect dielectric material layer 10 can be porous. In other embodiments, the interconnect dielectric material layer 10 can be non-porous. Examples of suitable dielectric materials that can be employed as the interconnect dielectric material layer 10 include, but are not limited to, silicon dioxide, undoped or doped silicate glass, silsesquioxanes, C doped oxides (i.e., organosilicates) that include atoms of Si, C, O and H, theremosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl.

The interconnect dielectric material layer 10 can have a dielectric constant (all dielectric constants mentioned herein are measured relative to a vacuum, unless otherwise stated) that is about 4.0 or less. In one embodiment, the interconnect dielectric material layer 10 has a dielectric constant of 2.8 or less. These dielectrics generally having a lower parasitic cross talk as compared to dielectric materials whose dielectric constant is greater than 4.0.

The interconnect dielectric material layer 10 can be formed by a deposition process such as, for example, chemical vapor deposition (CVD), plasma enhanced chemical vapor deposition (PECVD) or spin-on coating. The interconnect dielectric material layer 10 can have a thickness from 50 nm to 250 nm. Other thicknesses that are lesser than 50 nm, and greater than 250 nm can also be employed in the present application as the thickness of the interconnect dielectric material layer 10.

After providing the interconnect dielectric material layer 10, the at least one first opening 12 having the first critical dimension (CD-1) and the at least one second opening 14 having the second critical dimension (CD-2) that is greater than the first critical dimension (CD-1) are formed into the interconnect dielectric material layer 10. The at least one first opening 12 and the at least one second opening 14 can be formed utilizing one or more patterning processes. The one or more patterning processes can include lithography and etching, sidewall image transfer (SIT), or a direct self-assembly (DSA) process. In some embodiments, the at least one first opening 12 and the at least one second opening 14 are formed at the same time using a same patterning process. In another embodiment, the at least one first opening 12 can be formed prior to, or after, forming the at least one second opening 14. In the present application, each first opening 12 is spaced apart from a neighboring first opening 12 and each second opening 14 is spaced apart from a neighboring second opening 14. Also, and in the present application, the first and second openings are spaced apart from each other.

In one embodiment of the present application and as is shown in FIG. 1, both the at least one first opening 12 and the at least one second opening 14 are formed partially into the interconnect dielectric material layer 10. In such an embodiment, a portion of the interconnect dielectric material layer 10 is located beneath the bottom wall of both the at least one first opening 12 and the at least one second opening 14. In another embodiment of the present application (not shown), both the at least one first opening 12 and the at least one second opening 14 are formed entirely through the interconnect dielectric material layer 10. In such an embodiment, no portion of the interconnect dielectric material layer 10 is present directly above and directly below both the at least one first opening 12 and the at least one second opening 14. In yet another embodiment (not shown), the at least one first opening 12 is formed partially into the interconnect dielectric material layer, while the at least one second opening 14 is formed entirely through the interconnect dielectric material layer 10. In yet a further another embodiment (not shown), the at least one first opening 12 is formed entirely through the interconnect dielectric material layer, while the at least one second opening 14 is formed partially into the interconnect dielectric material layer 10.

As mentioned above, the at least one first opening 12 has a first critical dimension (CD-1) and the at least one second opening 14 has a second critical dimension (CD-2) that is greater than the first critical dimension (CD-1). In one embodiment of the present application, the second critical dimension (CD-2) of each second opening 14 is two times greater than the first critical dimension (CD-1) of each first opening 12. In one example, the first critical dimension (CD-1) is from 5 nm to 80 nm, and the second critical dimension (CD-2) is two times greater than the first critical dimension (CD-1). In the at least one first opening 12 having the first critical dimension (CD-1) copper fill needs to be avoided so as to circumvent increased resistivity in the small size openings.

Thus, and in the present application, each first opening 12 will house a hybrid metal-containing-containing electrically conductive structure having the first critical dimension (CD-1), and each second opening 14 will house a copper-containing electrically conductive structure having the second critical dimension (CD-2).

Referring now to FIG. 2, there is illustrated the exemplary structure of FIG. 1 after forming a first diffusion barrier layer 16 on the interconnect dielectric material layer 10 and within both the at least one first opening 12 and the at least one second opening 14. The first diffusion barrier layer 16 is a continuous layer which lines the at least one first opening 12 and the at least one second opening 14 and is present on a topmost surface of the interconnect dielectric material layer 10. In some embodiments of the present application, the first diffusion barrier layer 16 can be omitted from the structure.

The first diffusion barrier layer 16 is composed of a diffusion barrier material (e.g., metal, metal alloy or metal nitride) that prevents a conductive material from diffusing there through. Exemplary diffusion barrier materials include tantalum (Ta), tantalum nitride (TaN), titanium (Ti), titanium nitride (TiN), ruthenium (Ru), ruthenium nitride (RuN), an alloy of Ru—Ta, RuTaN, tungsten (W), or tungsten nitride (WN). The thickness of the first diffusion barrier layer 16 can vary depending on the deposition process used as well as the material employed. In some embodiments, the first diffusion barrier layer 16 can have a thickness from 0.3 nm to 50 nm; although other thicknesses for the first diffusion barrier layer 16 are contemplated and can be employed in the present application as long as the first diffusion barrier layer 16 does not entirely fill the at least one first opening 12 and the at least one second opening 14 that are formed into the interconnect dielectric material layer 10. The first diffusion barrier layer 16 can be formed by a deposition process including, for example, CVD, PECVD, atomic layer deposition (ALD), physical vapor deposition (PVD), sputtering, chemical solution deposition or plating.

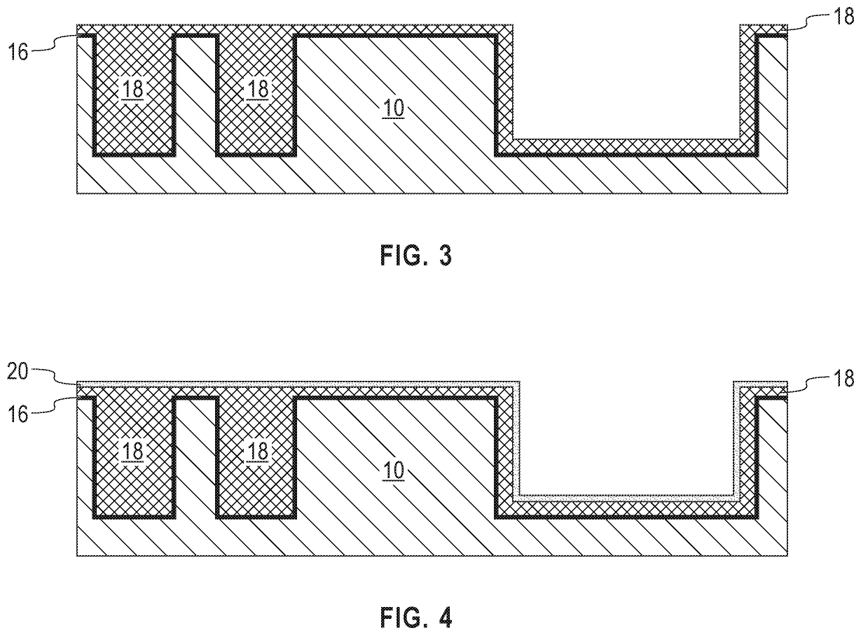

Referring now to FIG. 3, there is illustrated the exemplary structure of FIG. 2 after forming a hybrid metal-containing layer 18 on the first diffusion barrier layer 16, wherein the hybrid metal-containing layer 18 completely fills in the at least one first opening 12, while partially filling the at least one second opening 14. The term “hybrid metal-containing” denotes a metal or metal alloy that has a higher bulk resistivity than copper; pure copper generally has a bulk resistivity of 1.7 μΩ·cm at 21° C. and copper alloys generally have a bulk resistivity from 1.7 μΩ·cm to 3.0 μΩ·cm at 21° C., wherein μΩ equals microohms. Exemplary materials that have a higher bulk resistivity than copper that can be used in providing the hybrid metal-containing layer 18 include, but are not limited to, ruthenium (Ru), cobalt (Co), rhodium (Rh), nickel (Ni), tungsten (W), iridium (Jr), molybdenum (Mo) or alloys thereof. The hybrid metal or metal alloy typically has a bulk resistivity from to 3.5 μΩ·cm to 8.0 μΩ·cm at 21° C.

In one embodiment, the hybrid metal-containing layer 18 can be formed by a deposition process including, for example, CVD, PECVD, PVD or ALD. In another embodiment, the hybrid metal-containing layer 18 can be formed by a reflow process. A reflow process is a process in which a material is first deposited and then the deposited material is subjected to a reflow anneal that melts the material. The melted material flows into openings present in another material by capillary force/surface tension.

Because of the narrow dimension of the at least one first opening 12, the hybrid metal-containing layer 18 completely fills in the at least one first opening 12. Because of the wide dimension of the at least one second opening 14, the hybrid metal-containing layer 18 only partially fills the at least one second opening 14. In the at least one second opening 14, the deposited hybrid metal-containing layer 18 can have a thickness from 6 nm to 120 nm.

Referring now to FIG. 4, there is illustrated the exemplary structure of FIG. 3 after forming a second diffusion barrier layer 20 on the hybrid metal-containing layer 18. As is shown and because the volume of the at least one first opening 12 is entirely filled by the first diffusion barrier layer 16 and the hybrid metal-containing layer 18, the second diffusion barrier layer 20 is not formed into the at least one first opening 12, but is formed into the at least one second opening 14 whose volume at this point of the present application is only partially filled by the first diffusion barrier layer 16 and the hybrid metal-containing layer 18.

The second diffusion barrier layer 20 is composed of a diffusion barrier material (e.g., metal, metal alloy or metal nitride) that prevents a conductive material from diffusing there through. The diffusion barrier material that provides the second diffusion barrier layer 20 can be compositionally the same as, or compositionally different from, the diffusion barrier material that provided the first diffusion barrier layer 16. Exemplary diffusion barrier materials that can be used as the second diffusion barrier layer 20 include tantalum (Ta), tantalum nitride (TaN), titanium (Ti), titanium nitride (TiN), ruthenium (Ru), ruthenium nitride (RuN), an alloy of Ru—Ta, RuTaN, tungsten (W), or tungsten nitride (WN). The thickness of the second diffusion barrier layer 20 can vary depending on the deposition process used as well as the material employed. In some embodiments, the second diffusion barrier layer 20 can have a thickness from 2 nm to 25 nm; although other thicknesses for the second diffusion barrier layer 20 are contemplated and can be employed in the present application as long as the second diffusion barrier layer 20 does not entirely fill the at least one second opening 14 that is formed into the interconnect dielectric material layer 10; the at least one first opening 12 is entirely filled with the first diffusion barrier layer 16 and the hybrid metal-containing layer 18 at this point of the present application. The second diffusion barrier layer 20 can be formed utilizing one of the deposition processes mentioned above in forming the first diffusion barrier layer 16.

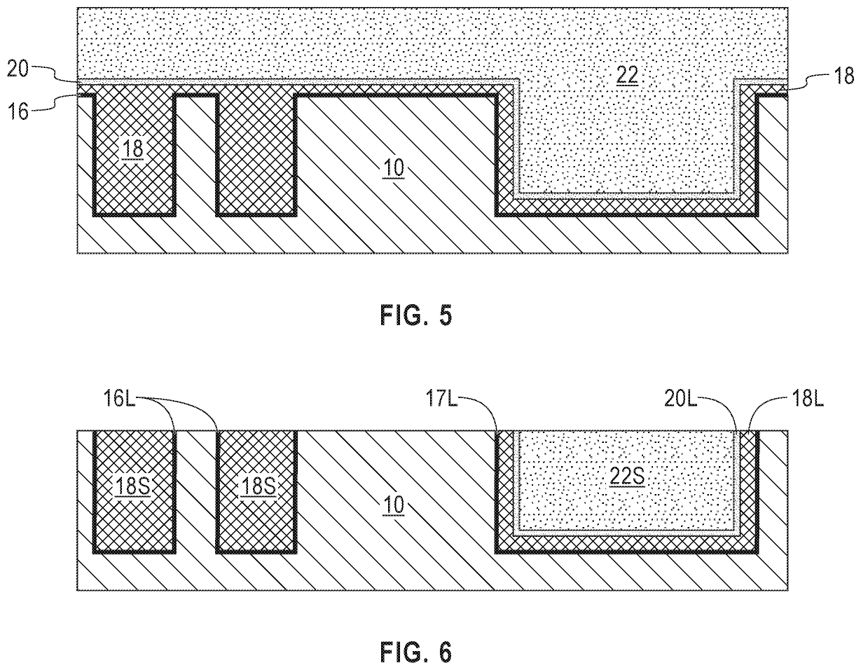

Referring now to FIG. 5, there is illustrated the exemplary structure of FIG. 4 after forming a copper-containing layer 22 on the second diffusion barrier layer 20. The copper-containing layer 22 completely fills in each of the second openings 14; the copper-containing layer 22 is excluded from being formed into the at least one first opening 12. The copper-containing layer 22 is composed of pure (i.e., unalloyed copper) or copper that is alloyed with aluminum (Al). In one embodiment, the copper-containing layer 22 can be formed utilizing a deposition process such as, for example, CVD, PECVD, sputtering, chemical solution deposition or plating. In one example, a bottom-up plating process can be employed in forming the copper-containing layer 22. In some embodiment, the copper-containing layer 22 can be formed utilizing a reflow process, as described above.

Referring now to FIG. 6, there is illustrated the exemplary structure of FIG. 5 after performing a planarization process to remove the copper-containing layer 22, the second diffusion barrier layer 20, the hybrid metal-containing layer 18, and the first diffusion barrier layer 16 that are present on a topmost surface of the interconnect dielectric material layer 10 (and thus outside the at least one first opening 12 and the at least one second opening 14), while maintaining the hybrid metal-containing layer 18 and the first diffusion barrier layer 16 in the at least one first opening 12 and maintaining the copper-containing layer 22, the second diffusion barrier layer 20, the hybrid metal-containing layer 18 and the first diffusion barrier layer 16 in the at least one second opening 14. The planarization process can include chemical mechanical polishing (CMP) and/or grinding. The planarization process stops on the topmost surface of the interconnect dielectric material layer 10.

The hybrid metal-containing layer 18 that is maintained in the at least one first opening 12 can be referred to herein as a hybrid metal-containing region 18S, while the first diffusion barrier layer 16 that is maintained in the at least one first opening 12 can be referred to herein as a diffusion barrier liner 16L. Collectively, the diffusion barrier liner 16L and the hybrid metal-containing region 18S that are present in the at least one first opening 12 provide a hybrid metal-containing electrically conductive structure that has the first critical dimension (CD-1) mentioned above. The hybrid metal-containing electrically conductive structure excludes a copper-containing region as well as another diffusion barrier liner.

As is shown in FIG. 6, the diffusion barrier liner 16L of the hybrid metal-containing electrically conductive structure directly contacts the interconnect dielectric material layer 10 and is located on sidewalls and a bottom wall of the hybrid metal-containing region 18S. As is further shown, the diffusion barrier liner 16L of the hybrid metal-containing electrically conductive structure has a topmost surface that is coplanar with a topmost surface of the hybrid metal-containing region 18S.

The copper-containing layer 22 that is maintained in the at least one second opening 14 can be referred to a copper-containing region 22S, the second diffusion barrier layer 20 that is maintained in the at least one second opening 14 can be referred to as a second diffusion barrier liner 20L, the hybrid metal-containing layer 18 that is maintained in the at least one second opening 14 can be referred as a hybrid metal-containing liner 18L, while the first diffusion barrier layer 16 that is maintained in the at least one second opening 14 can be referred to as a first diffusion barrier liner 17L. Collectively, the first diffusion barrier liner 17L, the hybrid metal-containing liner 18L, the second diffusion barrier liner 20L, and the copper-containing region 22S that are present in the at least one second opening 14 provide a copper-containing electrically conductive structure that has the second critical dimension (CD-2) mentioned above. The second diffusion barrier liner 20L is needed to preserve the reliability of the copper-containing electrically conductive structure.

The first diffusion barrier liner 17L of the copper-containing electrically conductive structure is compositionally the same as the diffusion barrier liner 16L of the hybrid metal-containing electrically conductive structure since both liners are derived from the first diffusion barrier layer 16. The diffusion barrier liner 16L of the hybrid metal-containing electrically conductive structure lines the interconnect dielectric material layer 10 exposed by the at least one first opening 12, while the first diffusion barrier liner 17L of the copper-containing electrically conductive structure lines the interconnect dielectric material layer 10 exposed by the at least one second opening 14. The hybrid metal-containing region 18S of the hybrid metal-containing electrically conductive structure and the hybrid metal-containing liner 18L of the copper-containing electrically conductive structure are composed of a compositionally same hybrid metal or metal alloy.

As is shown in FIG. 6, the first diffusion barrier liner 17L of the copper-containing electrically conductive structure directly contacts the interconnect dielectric material layer 10 and is located on sidewalls and a bottom wall of the hybrid metal-containing liner 18L, and the second diffusion barrier liner 20L is located on sidewalls and a bottom wall of the copper-containing region 22S and directly contacts the hybrid metal-containing liner 18L. As is further shown, the first diffusion barrier liner 17L of the copper-containing electrically conductive structure has a topmost surface that is coplanar with a topmost surface of each of the hybrid metal-containing liner 18L, the second diffusion barrier liner 20L, and the copper-containing region 22.

The hybrid metal-containing electrically conductive structure (16L/18S) and the copper-containing electrically conductive structure (17L/18L/20L/22S) are located in the same interconnect level and are embedded in a same interconnect dielectric material, i.e., interconnect dielectric material layer 10. The hybrid metal-containing electrically conductive structure (16L/18S) has a topmost surface that is coplanar with a topmost surface of both the copper-containing electrically conductive structure (17L/18L/20L/22S) and the interconnect dielectric material layer 10. In some embodiments, both the hybrid metal-containing electrically conductive structure 16L/18S) and the copper-containing electrically conductive structure (17L/18L/20L/22S) are partially embedded in the interconnect dielectric material layer 10.

The hybrid metal-containing electrically conductive structure (16L/18S) has a higher bulk resistivity than the copper-containing electrically conductive structure (17L/18L/20L/22S). In some embodiments, the hybrid metal-containing electrically conductive structure (16L/18S) can be used for signal distributions within the interconnect structure, while the copper-containing electrically conductive structure (17L/18L/20L/22S) can be used for power lines. Collectively, the BEOL interconnect structure containing the hybrid metal-containing electrically conductive structure (16L/18S) and the copper-containing electrically conductive structure (17L/18L/20L/22S) can be referred to as a hybrid interconnect structure.

In some embodiments of the present application (not shown), a metal cap can be selectively deposited on the topmost surface of both the hybrid metal-containing region 18S and the hybrid metal-containing region 18S.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A back-end-of-the-line (BEOL) interconnect structure comprising:
a hybrid metal-containing electrically conductive structure and a copper-containing electrically conductive structure embedded in an interconnect dielectric material layer, wherein the hybrid metal-containing electrically conductive structure has a first critical dimension and comprises a diffusion barrier liner and a hybrid metal-containing region, and the copper-containing electrically conductive structure has a second critical dimension that is greater than the first critical dimension and comprises a first diffusion barrier liner, a hybrid metal-containing liner, a second diffusion barrier liner and a copper-containing region, wherein the hybrid metal-containing region and the hybrid metal-containing liner are compositionally the same and include a metal or metal alloy that has a higher bulk resistivity than copper.

2. The BEOL interconnect structure of claim 1, wherein the hybrid metal-containing region and the hybrid metal-containing liner are composed of ruthenium (Ru), cobalt (Co), rhodium (Rh), nickel (Ni), tungsten (W), iridium (Jr), molybdenum (Mo) or alloys thereof.

3. The BEOL interconnect structure of claim 1, wherein the second critical dimension is two times greater than the first critical dimension.

4. The BEOL interconnect structure of claim 3, wherein the first critical dimension is from 5 nm to 80 nm.

5. The BEOL interconnect structure of claim 1, wherein the diffusion barrier liner of the hybrid metal-containing electrically conductive structure directly contacts the interconnect dielectric material layer and is located on sidewalls and a bottom wall of the hybrid metal-containing region.

6. The BEOL interconnect structure of claim 5, wherein the diffusion barrier liner of the hybrid metal-containing electrically conductive structure has a topmost surface that is coplanar with a topmost surface of the hybrid metal-containing region.

7. The BEOL structure of claim 1, wherein the first diffusion barrier liner of the copper-containing electrically conductive structure directly contacts the interconnect dielectric material layer and is located on sidewalls and a bottom wall of the hybrid metal-containing liner, and the second diffusion barrier liner is located on sidewalls and a bottom wall of the copper-containing region and directly contacts the hybrid metal-containing liner.

8. The BEOL interconnect structure of claim 7, wherein the first diffusion barrier liner of the copper-containing electrically conductive structure has a topmost surface that is coplanar with a topmost surface of each of the hybrid metal-containing liner, the second diffusion barrier liner, and the copper-containing region.

9. The BEOL interconnect structure of claim 1, wherein the hybrid metal-containing electrically conductive structure has a topmost surface that is coplanar with a topmost surface of both the copper-containing electrically conductive structure and the interconnect dielectric material layer.

10. The BEOL interconnect structure of claim 1, wherein both the hybrid metal-containing electrically conductive structure and the copper-containing electrically conductive structure are partially embedded in the interconnect dielectric material layer.

11. The BEOL interconnect structure of claim 1, wherein hybrid metal-containing electrically conductive structure excludes a copper-containing region and any other diffusion barrier liner.

12. A back-end-of-the-line (BEOL) interconnect structure comprising:
a hybrid metal-containing electrically conductive structure and a copper-containing electrically conductive structure embedded in an interconnect dielectric material layer, wherein the hybrid metal-containing electrically conductive structure has a first critical dimension and is entirely composed of a hybrid metal-containing region, and the copper-containing electrically conductive structure has a second critical dimension that is greater than the first critical dimension and comprises a hybrid metal-containing liner, a diffusion barrier liner and a copper-containing region, wherein the hybrid metal-containing region and the hybrid metal-containing liner are compositionally the same and include a metal or metal alloy that has a higher bulk resistivity than copper.

13. A method of forming a back-end-of-the-line (BEOL) interconnect structure, the method comprising:
forming an interconnect dielectric material layer that contains at least one first opening having a first critical dimension and at least one second opening having a second critical dimension that is greater than the first critical dimension;
forming a hybrid metal-containing layer within both the at least one first opening and the at least one second opening, wherein the hybrid metal-containing layer completely fills in the at least one first opening, while partially filling the at least one second opening;
forming a diffusion barrier layer on the hybrid metal-containing layer;
forming a copper-containing layer on the diffusion barrier layer; and
performing a planarization process to remove the copper-containing layer, the diffusion barrier layer, and the hybrid metal-containing layer that are present on the interconnect dielectric material layer, while maintaining the hybrid metal-containing layer in the at least one first opening and maintaining the copper-containing layer, the diffusion barrier layer, and the hybrid metal-containing layer in the at least one second opening.

14. The method of claim 13, wherein the hybrid metal-containing layer is composed of a metal or metal alloy having a higher bulk resistivity than copper.

15. The method of claim 14, wherein the hybrid metal-containing layer is composed of ruthenium (Ru), cobalt (Co), rhodium (Rh), nickel (Ni), tungsten (W), iridium (Jr), molybdenum (Mo) or alloys thereof.

16. The method of claim 13, wherein the second critical dimension is two times greater than the first critical dimension.

17. The method of claim 16, wherein the first critical dimension is from 5 nm to 80 nm.

18. The method of claim 13, wherein the hybrid metal-containing layer maintained in the at least one first opening after the planarization process provide a hybrid metal-containing electrically conductive structure, and the copper-containing layer, the diffusion barrier layer, and the hybrid metal-containing layer maintained in the at least one second opening after the planarization process provides a copper-containing electrically conductive structure, wherein the hybrid metal-containing electrically conductive structure has a topmost surface that is coplanar with a topmost surface of both the copper-containing electrically conductive structure and the interconnect dielectric material layer.

19. The method of claim 13, further comprising forming a first diffusion barrier material layer within both the at least one first opening and the at least one second opening prior to the forming of the hybrid metal-containing layer, and wherein during the planarization process, the first diffusion barrier layer is maintained in the at least one first opening and directly contacts the interconnect dielectric material layer, and the first diffusion barrier layer is also maintained in the at least one second opening and directly contacts the interconnect dielectric material layer.

20. The method of claim 13, wherein both the at least one first opening and the at least one second opening are partially formed into the interconnect dielectric material layer.
